(19) United States
(12) Patent Application Publication
(10) Pub. No.: US 2017/0186912 A1
(43) Pub. Date: Jun. 29, 2017

(54) NITRIDE SEMICONDUCTOR LIGHT-EMITTING ELEMENT

(71) Applicant: Sharp Kabushiki Kaisha, Sakai City, Osaka (JP)

(72) Inventor: Tomoya INOUE, Sakai City (JP)

(21) Appl. No.: 15/313,819

(22) PCT Filed: May 12, 2015
(86) PCT No.: PCT/JP2015/063548

§ 371 Date: Nov. 23, 2016

(30) Foreign Application Priority Data
Jun. 3, 2014 (JP) 2014-114859

(51) Int. Cl. H01L 33/32; H01L 33/00; H01L 33/42; H01L 33/12; H01L 33/06; H01L 33/24

(52) U.S. Cl. CPC H01L 33/32; H01L 33/06; H01L 33/24; H01L 33/42; H01L 33/12; H01L 33/0075

(57) ABSTRACT

A nitride semiconductor light-emitting element includes a substrate; and an n-type nitride semiconductor layer, a light-emitting layer, and a p-type nitride semiconductor layer. The n-type nitride semiconductor layer includes a first n-type nitride semiconductor layer, a second n-type nitride semiconductor layer, and a third n-type nitride semiconductor layer. The n-type dopant concentration in the second n-type nitride semiconductor layer is lower than that in the first n-type nitride semiconductor layer. The n-type dopant concentration in the third n-type nitride semiconductor layer is higher than that in the second n-type nitride semiconductor layer. A V-pit structure is partially formed in the second n-type nitride semiconductor layer, the third n-type nitride semiconductor layers, and the light-emitting layer. The average position of the starting point of the V-pit structure is present in the second n-type nitride semiconductor layer.

### TECHNICAL FIELD

The present invention relates to a nitride semiconductor light-emitting element.

### BACKGROUND ART

Group III-V compound semiconductor materials containing nitrogen (hereinafter referred to as “nitride semiconductor materials”) have band gap energy corresponding to the energy of light having wavelengths from the infrared region to the ultraviolet region. Therefore, the nitride semiconductor materials are useful as materials for light-emitting elements which emit light having wavelengths from the infrared region to the ultraviolet region, as materials for light-receiving elements which receive light having wavelengths within these regions, or the like.

Also, the nitride semiconductor materials have strong bonding force between atoms constituting a nitride semiconductor, a high dielectric breakdown voltage, and a high saturation electron speed. Therefore, the nitride semiconductor materials are useful as materials for electronic devices such as a high-frequency transistor with high temperature resistance and high output, and the like. Further, the nitride semiconductor materials cause substantially no harm to the environment and thus attract attention as easily handleable materials.

A nitride semiconductor light-emitting element using such a nitride semiconductor material generally has a quantum well structure as a light-emitting layer. When a voltage is applied to a nitride semiconductor light-emitting element using a quantum well structure as a light-emitting layer, electrons and holes are recombined in a quantum well layer constituting the light-emitting layer, thereby emitting light. The light-emitting layer having the quantum well structure may have a single quantum well (SQW) structure or a multiple quantum well (MQW) structure in which quantum well layers and barrier layers are alternately stacked.

In general, an InGaN layer is used as the quantum well layer, and a GaN layer is used as the barrier layer. In this case, for example, a blue LED (Light Emitting Device) having an emission peak wavelength of about 450 nm can be produced. In addition, a white LED can be produced by combining the blue LED with a yellow phosphor.

In general, a GaN layer or InGaN layer is used as an n-type nitrogen semiconductor layer contained in a nitrogen semiconductor light-emitting element. The n-type nitride semiconductor is considered to have the function as a contact layer with an n-side electrode and also the function as a layer which relaxes strain of a current injection layer or a light-emitting layer or the function as a layer which forms a V-shaped pit structure. However, the action of these functions of the n-type nitride semiconductor layer on the characteristics of a nitride semiconductor light-emitting element is not completely clarified.

For example, Patent Literature 1 (Japanese Unexamined Patent Application publication No. 11-330554) describes a nitride semiconductor element including an n-side multilayer film layer provided below an active layer and having a nitride semiconductor layer containing In. Patent Literature 1 describes that the output of a light-emitting element is improved by some function of the n-side multilayer film layer and also describes that although details are unclear, the reason for this is supposed to be due to improvement in crystallinity of the active layer.

Also, Patent Literature 2 (Japanese Unexamined Patent Application publication No. 8-23124) describes that when a second n-type layer having a high carrier concentration is formed on the active layer side so as to be in contact with a first n-type layer, it is possible to realize an element improved in optical output due to uniform plane emission from the active layer.

In addition, it is known that a pit structure with a shape called a V pit (V-shaped pit, a recess with a V-shaped section), V defect, or inverted hexagonal pyramid defect is formed in a nitride semiconductor light-emitting element.

Patent Literature 3 (Japanese Unexamined Patent Application publication No. 2013-187484) describes a nitride semiconductor light-emitting element in which an n-type nitride semiconductor layer, a V-pit generation layer, an intermediate layer, a multiple quantum well light-emitting layer, and a p-type nitride semiconductor layer are stacked in that order. Patent Literature 3 also describes that when a multilayer structure (in the multilayer structure, a plurality of nitride semiconductor layers having different band gap energies are stacked) is provided between the V-pit generation layer and the intermediate layer, a decrease in emission efficiency during operation at a high temperature and high current can be prevented, and thus a defective rate due to ESD (Electrostatic Discharge) can be decreased.

Further, Non Patent Literature 1 reports the function of a V pit in a light-emitting layer having a MQW structure. Non Patent Literature 1 describes that when a V pit is present in the light-emitting layer having the MQW structure, the width of a quantum well layer in the inclined surface of the V pit is narrowed, and thus the electrons and holes injected into the quantum well layer are inhibited from reaching threading dislocation, resulting in the suppression of nonradiative recombination in the light-emitting layer.

### CITATION LIST

### Patent Literature

PTL 1: Japanese Unexamined Patent Application Publication No. 11-330554
PTL 2: Japanese Unexamined Patent Application Publication No. 8-23124
PTL 3: Japanese Unexamined Patent Application Publication No. 2013-187484

### Non Patent Literature

NPL 1: A. Hangleiter, F. Hitzel, C. Netzel, D. Fuhrmann, U. Rossow, G. Ade, and P. Hinze, “Suppression of Nonradiative Recombination by V-Shaped Pits in GaInN/GaN Quantum Wells Produces a Large Increase in the Light Emission Efficiency”, Physical Review Letters 95, 127402 (2005)

### SUMMARY OF INVENTION

### Technical Problem

Although a reason is unknown, the optical output can be increased when a nitride semiconductor light-emitting element is produced by using an n-type nitride semiconductor layer containing In. However, In is an expensive raw material, and a multilayer structure including nitride semiconductor layers is complicated. Therefore, productivity of a nitride semiconductor light-emitting element may be decreased, and the cost of a nitride semiconductor light-emitting element may be increased.

On the other hand, a nitride semiconductor light-emitting element can be relatively easily produced by using an n-type nitride semiconductor layer not containing In. However, the optical output is decreased. In particular, during operation at a high temperature or high current, the emission efficiency is decreased, thereby causing significant decrease in optical output. Thus, for example, when a nitride semiconductor light-emitting element is used in lighting application or the like, there occurs a problem that optical output is greatly decreased after the time elapsed from lighting as compared with the optical output immediately after lighting.

Also, for example, when a light-emitting element having an emission peak wavelength within a short wavelength region of 360 nm to 420 nm is produced by using an n-type nitride semiconductor layer containing In, the n-type nitride semiconductor layer functions as a light-absorbing layer which absorbs light from a light-emitting layer. Therefore, a decrease in optical output may be caused during operation even at room temperature.

An object of the present disclosure is to enhance the optical output of a nitride semiconductor light-emitting element during both the operation at room temperature and the operation at a high temperature (the specification includes a case in which the operating temperature of a nitride semiconductor light-emitting element is increased by an operation at a high current or high current density).

### Solution to Problem

A nitride semiconductor light-emitting element of the present invention includes a substrate and an n-type nitride semiconductor layer, a light-emitting layer having a single quantum well structure a multiple quantum well structure, and a p-type nitride semiconductor layer, which are provided in order on the substrate. The n-type nitride semiconductor layer includes a first n-type nitride semiconductor layer, a second n-type nitride semiconductor layer, and a third n-type nitride semiconductor layer which are provided in order from the substrate side to the light-emitting layer side. The n-type dopant concentration in the second n-type nitride semiconductor layer is lower than that in the first n-type nitride semiconductor layer. The n-type dopant concentration in the third n-type nitride semiconductor layer is higher than that in the second n-type nitride semiconductor layer. A V-pit structure is partially formed in the second n-type nitride semiconductor layer, the third n-type nitride semiconductor layer, and the light-emitting layer. The average position of the starting point of the V-pit structure is present in the second n-type nitride semiconductor layer.

The diameter of the V-pit structure at the lower surface of the light-emitting layer is preferably 40 nm or more and 80 nm or less.

The average position of the starting point of the V-pit structure is preferably present 30 nm or more away from the lower surface of the second n-type nitride semiconductor layer.

The third n-type nitride semiconductor layer is preferably composed of GaN or AlGaN.

### Advantageous Effects of Invention

According to the present invention, the optical output of a nitride semiconductor light-emitting element can be enhanced during both the operation at room temperature and the operation at a high temperature.

### BRIEF DESCRIPTION OF DRAWINGS

FIG. 1 is a sectional view of a nitride semiconductor light-emitting element according to an embodiment of the present invention.

FIG. 2 is a graph showing the results of examples.

### DESCRIPTION OF EMBODIMENTS

The present invention is described below by using the drawings. In the drawings of the present invention, the same reference numeral denotes the same portion or corresponding portion. The dimensional relationship between length, width, thickness, depth, etc. is appropriately changed for clarifying and simplifying the drawings, not presents an actual dimensional relationship. The terms used in the specification are defined, and then the present invention is described below.

### Definition of Terms in the Specification

The term “barrier layer” represents a layer held between quantum well layers in a light-emitting layer. A barrier layer not held between quantum well layers is denoted by “first barrier layer” or “final barrier layer”, and the denotation is different from a layer held between quantum well layers.

The “dopant concentration” and the “carrier concentration” representing the concentration of electrons or holes produced with doping with an n-type dopant or p-type dopant are used. The relation between the “dopant concentration” and the “carrier concentration” is described later.

The “carrier gas” represents gas other than group III raw material gas, group V raw material gas, and dopant raw material gas. The atoms constituting the carrier gas are introduced into a nitride semiconductor layer or the like.

The term “undoped” represents the state of being not doped with a dopant (n-type dopant or p-type dopant) intentionally. Therefore, an “undoped layer” may contain a dopant due to diffusion of a dopant from a layer adjacent to the undoped layer.

The “n-type nitride semiconductor layer” may include a p-type layer or undoped layer having a low carrier concentration and such a thickness as not to practically inhibit an electron flow. The expression “not to practically inhibit” represents that the operating voltage of a nitride semiconductor light-emitting element is at a practical level.

The “p-type nitride semiconductor layer” may include an n-type layer or undoped layer having a low carrier concentration and such a thickness as not to practically inhibit a hole flow. The expression “not to practically inhibit” represents that the operating voltage of a nitride semiconductor light-emitting element is at a practical level.

The term “AlGaN” represents containing Al, Ga, N as atoms, and the composition thereof is not particularly limited. The same is true for the terms “InGaN”, “AlGaInN”, and “AlON”.

The term “nitride semiconductor” represents that the atomic number ratio of nitrogen (N) to another element (for example, Al, Ga, or In) is ideally 1:1. However, the “nitride semiconductor” includes a nitride semiconductor containing a dopant and also includes a case in which the atomic number ratio is different from 1:1. In the case of the term “AlₓGa₁₋ₓN”, the term includes not only a case in which the atomic number ratio of nitrogen (N) to another element (Al or Ga) is 1:1 but also a case in which the atomic number ratio is different from 1:1.

It is assumed that the band gap energy Eg (unit: eV) of a nitride semiconductor and the mixed crystal ratio x of In or Al satisfy expressions (I) and (II) below described in Joachim Piprek et. al., “Semiconductor Optoelectric Devices”, Academic Press, 2003, p. 191.

Eg(InₓGa₁₋ₓN)=1.89x+3.42(1−x)−3.8(1−x) Expression (I)

Eg(AlₓGa₁₋ₓN)=6.28x+3.42(1−x)−1.3(1−x) Expression (II)

### [Configuration of Nitride Semiconductor Light-Emitting Element]

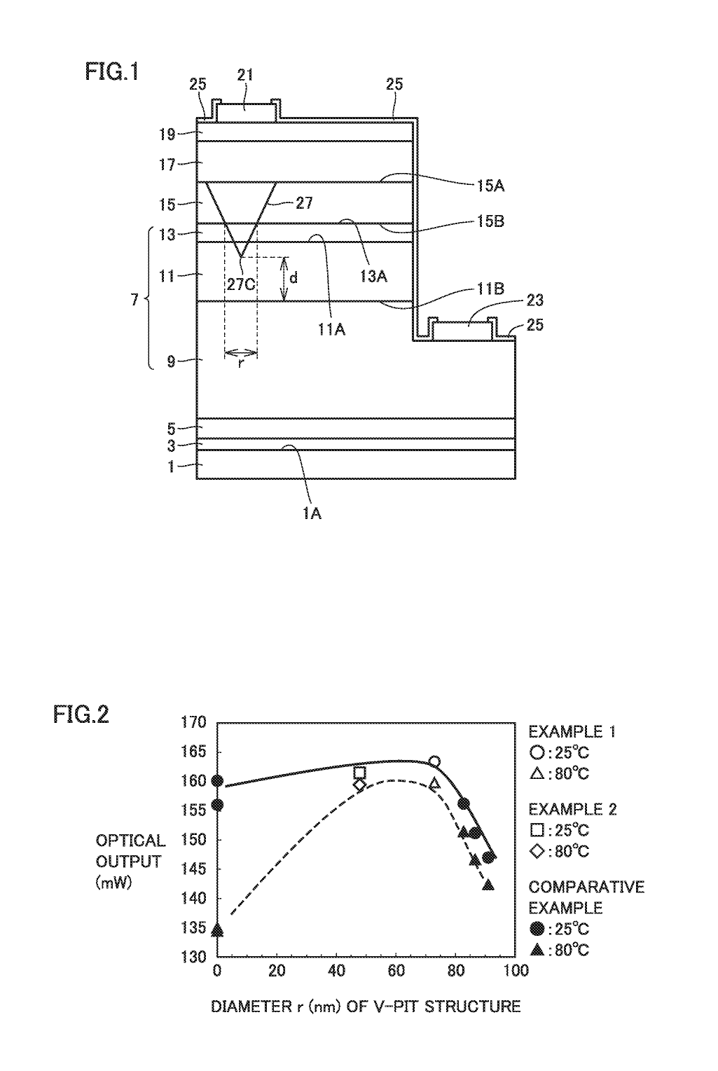

FIG. 1 is a sectional view of a nitride semiconductor light-emitting element according to an embodiment of the present invention. A nitride semiconductor light-emitting element includes a substrate 1 and a buffer layer 3, an underlayer 5, an n-type nitride semiconductor layer 7, a light-emitting layer 15, and a p-type nitride semiconductor layer 17, which are provided in order on the substrate 1. The n-type nitride semiconductor layer 7 includes a first n-type nitride semiconductor layer 9, a second n-type nitride semiconductor layer 11, and a third n-type nitride semiconductor layer 13 which are provided in order from the substrate 1 side to the light-emitting layer 15. A V-pit structure 27 is partially formed in the second n-type nitride semiconductor layer 11, the third n-type nitride semiconductor layer 13, and the light-emitting layer 15.

A transparent electrode layer 19 is provided on the p-type nitride semiconductor layer 17, and a p-side electrode 21 is provided on the transparent electrode layer 19. Also, an n-side electrode 23 is provided on an exposed surface of the first n-type nitride semiconductor layer 9. The surface of the nitride semiconductor light-emitting element is covered with a transparent insulating layer 25, but a portion of the upper surface of the p-side electrode 21 and a portion of the upper surface of the n-side electrode 23 are exposed from the transparent insulating layer 25.

### <Substrate>

For example, a substrate composed of sapphire, GaN, SiC, Si, ZnO, or the like can be used as the substrate 1. The thickness of the substrate 1 is not particularly limited. During growth of a nitride semiconductor layer such as the n-type nitride semiconductor layer 7 or the like, the thickness of the substrate 1 is preferably 900 μm or more and 1300 μm or less, while during the use of the nitride semiconductor light-emitting element, the thickness of the substrate 1 is preferably 50 μm or more and 300 μm or less.

An uneven shape having recesses and protections may be formed on the upper surface 1A of the substrate 1. The shape of each of the recesses and the projections is not particularly limited, and an arrangement of the recesses and the projections on the upper surface 1A is not particularly limited. For example, the projections are preferably provided on the upper surface 1A to be located at positions corresponding to the apexes of a substantially regular triangle. The distance between the apexes of the adjacent projections is preferably 1 μm or more and 5 μm or less. Each of the projections preferably has a substantially circular shape on the upper surface 1A. When the longitudinal sectional shape of each of the projections is a trapezoid, the top of the trapezoid is preferably rounded. At least a portion of the upper surface 1A may be flat.

In addition, the substrate 1 may be removed after the nitride semiconductor layers are grown on the upper surface 1A of the substrate 1. That is, the nitride semiconductor light-emitting element according to the embodiment of the present invention may not include the substrate 1.

### <Buffer Layer>

Examples of the buffer layer 3 which can be used include an AlON layer (O-to-N ratio of several atomic %), a layer composed of a nitride semiconductor material represented by general formula Alₛ₀Gaₜ₀Oᵤ₀N₁₋ᵤ₀ (0≦s0≦1, 0≦t0≦1, 0≦u0≦1, s0+t0+u0≠0), and the like.

The AlON layer constituting the buffer layer 3 contains N, a small part of (0.5 atomic % or more and 2 atomic % or less) which is preferably substituted by oxygen. In this case, the buffer layer 3 is formed to extend in a normal direction to the growth surface of the substrate 1, and thus the buffer layer 3 containing an aggregate of columnar crystals of uniform crystal grains can be produced.

The AlON layer formed by a known sputtering method is preferably used as the buffer layer 3. In this case, the crystal quality of the underlayer 5 can be enhanced. The crystal quality of the underlayer 5 can be confirmed from the half width of a peak appearing in a diffraction intensity curve measured by an X-ray rocking curve diffraction method.

For example, a GaN layer formed by a MOCVD (Metal Organic Chemical Vapor Deposition) method at a low temperature of about 500° C. may be used as the buffer layer 3.

The thickness of the buffer layer 3 is not particularly limited but is preferably 3 nm or more and 100 nm or less and more preferably 5 nm or more and 50 nm or less.

### <Underlayer>

Examples of the underlayer 5 which can be used include a layer composed of a nitride semiconductor material represented by general formula Alₓ₀Ga_{y0}In_{z0}N (0≦x0≦1, 0≦y0≦1, 0≦z0≦1, x0+y0+z0≠0), and the like.

A nitride semiconductor layer containing Ga as a group III element is preferably used as the underlayer 5. In this case, it is possible to form the underlayer 5 without transmitting crystal defects (dislocation or the like) in the buffer layer 3 including an aggregate of columnar crystals.

The underlayer 5 may be an undoped layer or an n-type layer. For example, the underlayer 5 may be doped with an n-type dopant within a range of 1×10⁶/cm³ or more and 1×10²⁰/cm³ or less. For example, at least one of Si, Ge, and Sn can be used as the n-type dopant, and Si is preferably used. When Si is used as the n-type dopant, silane or disilane is preferably used as a raw material gas of the n-type dopant. The material of the n-type dopant and the material of the n-type dopant raw material gas are true for the n-type nitride semiconductor layers described below.

When the thickness of the underlayer 5 is increased as much as possible, the defects in the underlayer 5 are decreased, but there is the problem of increasing warping of a wafer (including the nitride semiconductor layers formed on the upper surface of the substrate) due to a difference in thermal expansion coefficient between the substrate 1 and the underlayer 5. In addition, when the thickness of the underlayer 5 is increased to some extent or more, the effect of decreasing defects in the underlayer 5 is saturated. Therefore, the thickness of the underlayer 5 is preferably 1 μm or more and 8 μm or less and more preferably 3 μm or more and 5 μm or less.

### <N-Type Nitride Semiconductor Layer>

<First n-Type Nitride Semiconductor Layer>

For example, a layer doped with an n-type dopant and composed of a nitride semiconductor material represented by general formula Alₓ₁Ga_{y1}In_{z1}N (0≦x1≦1, 0≦y1≦1, 0≦z1≦1, x1+y1+z1≠0) can be used as the first n-type nitride semiconductor layer 9. A layer doped with an n-type dopant and composed of a nitride semiconductor material represented by general formula Alₓ₁Ga₁₋ₓ₁N (0≦x1≦1, preferably 0≦x1≦0.5, more preferably 0≦x1≦0.1) is preferably used as the first n-type nitride semiconductor layer 9.

The n-type dopant concentration in the first n-type nitride semiconductor layer 9 is preferably 2×10¹⁸/cm³ or more. This can enhance the emission efficiency of the nitride semiconductor light-emitting element even during the operation at a high current density. The n-type dopant concentration in the first n-type nitride semiconductor layer 9 is more preferably 5×10¹⁸/cm³ or more and 5×10¹⁹/cm³ or less.

The first n-type nitride semiconductor layer 9 also functions as a contact layer with the n-side electrode 23. Therefore, in the first n-type nitride semiconductor layer 9, a portion functioning as the contact layer with the n-side electrode 23 preferably has an n-type dopant concentration of 1×10¹⁸/cm³ or more.

Decreasing the thickness of the first n-type nitride semiconductor layer 9 decreases the resistance of the first n-type nitride semiconductor layer, but causes an increase in manufacturing cost of the nitride semiconductor light-emitting element. In view of this, the thickness of the first n-type nitride semiconductor layer 9 is preferably 1 μm or more and 10 μm or less but is not limited to this range.

The first n-type nitride semiconductor layer 9 may be a single layer or may have a multilayer structure formed by stacking two or more layers different from each other in at least one of the composition and the dopant concentration. When the first n-type nitride semiconductor layer 9 has the multilayer structure described above, at least one of the layers constituting the first n-type nitride semiconductor layer 9 may be different from other layers in at least one of the composition and the dopant concentration. When the first n-type nitride semiconductor layer 9 has the multilayer structure described above, all layers constituting the first n-type nitride semiconductor layer 9 may have the same thickness or at least one of the layers constituting the first n-type nitride semiconductor layer 9 may have a thickness different from those of other layers.

When the first n-type nitride semiconductor layer 9 has the multilayer structure described above, the n-type dopant concentration in the first n-type nitride semiconductor layer 9 is determined by dividing the total amount of the n-type dopant contained in the layers constituting the first n-type nitride semiconductor layer 9 by the volume of the first n-type nitride semiconductor layer 9.

<Second n-Type Nitride Semiconductor Layer>

For example, a layer doped with an n-type dopant and composed of a nitride semiconductor material represented by general formula Alₓ₂Ga_{y2}In_{z2}N (0≦x2≦1, 0≦y2≦1, 0≦z2≦1, x2+y2+z2≠0) can be used as the second n-type nitride semiconductor layer 11. A layer doped with an n-type dopant and composed of a nitride semiconductor material represented by general formula Alₓ₂Ga₁₋ₓ₂N (0≦x2≦1, preferably 0≦x2≦0.3, more preferably 0≦x2≦0.1) or a layer doped with an n-type dopant and composed of a nitride semiconductor material represented by general formula In_{z2}Ga_{1-z2}N (0≦z2≦1, preferably 0≦z2≦0.3, more preferably 0≦z2≦0.1) is preferably used as the second n-type nitride semiconductor layer 11.

The n-type dopant concentration in the second n-type nitride semiconductor layer 11 is preferably lower than the n-type dopant concentration in the first n-type nitride semiconductor layer 9 and is more preferably 1×10¹⁹/cm³ or less. The second n-type nitride semiconductor layer 11 may be an undoped layer.

The thickness of the second n-type nitride semiconductor layer 11 is not particularly limited but is preferably 50 nm or more and 500 nm or less.

The second n-type nitride semiconductor layer 11 may be a single layer or may have a multilayer structure formed by stacking two or more layers different from each other in at least one of the composition and the dopant concentration. When the second n-type nitride semiconductor layer 11 has the multilayer structure described above, at least one of the layers constituting the second n-type nitride semiconductor layer 11 may be different from other layers in at least one of the composition and the dopant concentration. When the second n-type nitride semiconductor layer 11 has the multilayer structure described above, all layers constituting the second n-type nitride semiconductor layer 11 may have the same thickness or at least one of the layers constituting the second n-type nitride semiconductor layer 11 may have a thickness different from those of other layers.

When the second n-type nitride semiconductor layer 11 has the multilayer structure described above, the n-type dopant concentration in the second n-type nitride semiconductor layer 11 is determined by dividing the total amount of the n-type dopant contained in the layers constituting the second n-type nitride semiconductor layer 11 by the volume of the second n-type nitride semiconductor layer 11.

<Third n-Type Nitride Semiconductor Layer>

For example, a layer doped with an n-type dopant and composed of a nitride semiconductor material represented by general formula Alₓ₃Ga_{y3}In_{z3}N (0≦x3≦1, 0≦y3≦1, 0≦z3≦1, x3+y3+z3≠0) can be used as the third n-type nitride semiconductor layer 13. A layer doped with an n-type dopant and composed of a nitride semiconductor material (for example, GaN or AlGaN) containing at least one of Ga and Al is preferably used as the third n-type nitride semiconductor layer 13.

The n-type dopant concentration in the third n-type nitride semiconductor layer 13 is preferably higher than the n-type dopant concentration in the second n-type nitride semiconductor layer 11 and is more preferably two or more times as high as the n-type dopant concentration in the second n-type nitride semiconductor layer 11. The n-type dopant concentration in the third n-type nitride semiconductor layer 13 is preferably, for example, 2×10¹⁸/cm³ or more and 2×10¹⁹/cm³ or less.

The thickness of the third n-type nitride semiconductor layer 13 is preferably more than 0 nm and 100 nm or less and more preferably 5 nm or more and 100 nm or less. When the thickness of the third n-type nitride semiconductor layer 13 is 5 nm or more, the drive voltage can be decreased. When the thickness of the third n-type nitride semiconductor layer 13 is 100 nm or less, a depletion layer is extended in the third n-type nitride semiconductor layer 13 even with a reverse voltage applied, and thus a decrease in electrostatic breakdown voltage can be prevented.

The third n-type nitride semiconductor layer 13 may be a single layer or may have a multilayer structure formed by stacking two or more layers different from each other in at least one of the composition and the dopant concentration. When the third n-type nitride semiconductor layer 13 has the multilayer structure described above, at least one of the layers constituting the third n-type nitride semiconductor layer 13 may be different from other layers in at least one of the composition and the dopant concentration. When the third n-type nitride semiconductor layer 13 has the multilayer structure described above, all layers constituting the third n-type nitride semiconductor layer 13 may have the same thickness or at least one of the layers constituting the third n-type nitride semiconductor layer 13 may have a thickness different from those of other layers.

When the third n-type nitride semiconductor layer 13 has the multilayer structure described above, the n-type dopant concentration of the third n-type nitride semiconductor layer 13 is determined by dividing the total amount of the n-type dopant contained in the layers constituting the third n-type nitride semiconductor layer 13 by the volume of the third n-type nitride semiconductor layer 13.

<Composition (in) in n-Type Nitride Semiconductor Layer 7>

When the emission peak wavelength of the light-emitting layer 15 is 360 nm or more and 420 nm or less, the n-type nitride semiconductor layer 7 preferably does not contain In. When the n-type nitride semiconductor layer 7 does not contain In, light having an emission peak wavelength within a range of 360 nm or more and 420 nm or less can be prevented from being absorbed by the n-type nitride semiconductor layer 7. Therefore, even when the light-emitting layer 15 emits light having an emission peak wavelength within a range of 360 nm or more and 420 nm or less, the light extraction efficiency can be maintained high, and thus the optical output can be maintained high.

The expression “the n-type nitride semiconductor layer 7 does not contain In” represents a case in which the nitride semiconductor material constituting the first n-type nitride semiconductor layer 9 is represented by general formula Alₓ₁Ga_{y1}N (0≦x1≦1, 0≦y1≦1, x1+y1≠0), the nitride semiconductor material constituting the second n-type nitride semiconductor layer 11 is represented by general formula Alₓ₂Ga_{y2}N (0≦x2≦1, 0≦y2≦1, x2+y2≠0), and the nitride semiconductor material constituting the third n-type nitride semiconductor layer 13 is represented by general formula Alₓ₃Ga_{y3}N (0≦x3≦1, 0≦y3≦1, x3+y3≠0).

<N-Type Dopant Concentration in n-Type Nitride Semiconductor Layer 7>

As described above, the n-type dopant concentration in the second n-type nitride semiconductor layer 11 is lower than the n-type dopant concentration in the first n-type nitride semiconductor layer 9, and the n-type dopant concentration in the third n-type nitride semiconductor layer 13 is higher than the n-type dopant concentration in the second n-type nitride semiconductor layer 11.

When the n-type dopant concentration in the second n-type nitride semiconductor layer 11 is lower than the n-type dopant concentration in the first n-type nitride semiconductor layer 9, ESD resistance is improved, and leakage failure (failure caused by the occurrence of leak current) is decreased. Therefore, the manufacturing yield of the nitride semiconductor light-emitting element is improved.

When the n-type dopant concentration in the third n-type nitride semiconductor layer 13 is higher than the n-type dopant concentration in the second n-type nitride semiconductor layer 11, the electron injection efficiency is increased, and thus the operating voltage is decreased. Also, the optical output is increased, thereby increasing the power efficiency.

The n-type dopant concentration in the first n-type nitride semiconductor layer 9 may be either higher or lower than the n-type dopant concentration in the third n-type nitride semiconductor layer 13.

### <Light-Emitting Layer>

The light-emitting layer 15 may have a SQW structure or a MQW structure. The light-emitting layer 15 having a MQW structure is described below.

The light-emitting layer 15 having a MQW structure includes a quantum well layer, a barrier layer, a first barrier layer, and a final barrier layer. The first barrier layer is provided on the upper surface 13A of the third n-type nitride semiconductor layer 13, the final barrier layer is in contact with the p-type nitride semiconductor layer 17, and the quantum well layer is held between the barrier layers.

In addition, one or more other semiconductor layers different from the barrier layers and the quantum well layer may be provided between the barrier layer and the quantum well layer. Further, the length of one period (total of the thickness of one barrier layer and the thickness of one quantum well layer) of the light-emitting layer 15 is preferably 5 nm or more and 100 nm or less.

### (Quantum Well Layer)

A layer composed of a nitride semiconductor material represented by general formula Al_{c1}Ga_{d1}In_{(1-c1-d1)}N (0≦c1<1, 0<d1≦1) can be independently used as each of the quantum well layers. A layer composed of a nitride semiconductor material represented by general formula Inₑ₁Ga₍₁₋ₑ₁₎N (0<e1≦1) not containing Al is preferably used. The band gap energy of the quantum well layer can be changed by changing the In composition of the quantum well layer. For example, in the case of emission of ultraviolet light at a wavelength of 375 nm or less, the band gap energy of the light-emitting layer is required to be increased. In this case, the quantum well layer preferably contains Al.

Among a plurality of quantum well layers, some of the quantum well layers disposed on the n-type nitride semiconductor layer 7 side preferably contain an n-type dopant. In this case, the drive voltage of the nitride semiconductor light-emitting element can be decreased.

The thickness of each of the quantum well layers is preferably 1 nm or more and 7 nm or less. When the thickness of each of the quantum well layers is 1 nm or more and 7 nm or less, the emission efficiency of the nitride semiconductor light-emitting element during operation at a high current density can be enhanced.

In a plurality of quantum well layers, the quantum well layers preferably have the same thickness. In a plurality of quantum well layers, when the quantum well layers have the same thickness, the quantum well layers have the same quantum level, and thus the quantum well layers emit light at the same wavelength due to recombination of electrons and holes. This narrows the width of a peak appearing in an emission spectrum of the nitride semiconductor light-emitting element.

On the other hand, in a plurality of quantum well layers, when the quantum well layers have intentionally different from each other in at least one of the thickness and the composition, the width of a peak appearing in an emission spectrum of the nitride semiconductor light-emitting element is widened. Whether or not the thicknesses or compositions of the quantum well layers are the same is determined according to application of the nitride semiconductor light-emitting element.

The number of the quantum well layers contained in the light-emitting layer 15 is not particularly limited but is preferably 1 or more and 20 or less, more preferably 3 or more and 15 or less, and still more preferably 4 or more and 12 or less.

### (Barrier Layer, First Barrier Layer, and Final Barrier Layer)

A nitride semiconductor material having a higher band gap energy than the nitride semiconductor material constituting the quantum well layers can be used as each of the barrier layers. A layer composed of a nitride semiconductor material represented by general formula Al_{f}Ga_{g}In_{(1-f-g)}N (0≦f<1, 0<g≦1) can be independently used as each of the barrier layers. A layer composed of a nitride semiconductor material represented by general formula AlₕGa₍₁₋ₕ₎N (0<h≦1) containing Al is preferably used. A layer composed of a nitride semiconductor material represented by general formula AlₕGa₍₁₋ₕ₎N (0<h<1) containing Ga and Al is more preferably used. The same is true for the composition of the first barrier layer and the composition of the final barrier layer.

Each of the barrier layer and the first barrier layer may be an undoped layer, but the n-type dopant concentration in each of the barrier layer and the first barrier layer is not particularly limited and is preferably properly determined according to demand. For example, among the plurality of barrier layers, the barrier layer located on the n-type nitride semiconductor layer 7 side is doped with an n-type dopant and the barrier layer located on the p-type nitride semiconductor layer 17 side is doped with an n-type dopant at a concentration lower than that of the barrier layer located on the n-type nitride semiconductor layer 7 side or not doped with an n-type dopant (undoped).

Each of the barrier layer, the first barrier layer, and the final barrier layer may be doped with a p-type dopant due to thermal diffusion during growth of the p-type nitride semiconductor layer 17.

The thickness of each of the barrier layers is not particularly limited but is preferably 1 nm or more and 10 nm or less and more preferably 3 nm or more and 7 nm or less. Decreasing the thickness of each of the barrier layers decreases the operating voltage. However, when the thickness of each of the barrier layers is less than 1 nm, the emission efficiency during operation at a high current density may be decreased. The thickness of the first barrier layer is not particularly limited but is preferably 1 nm or more and 10 nm or less. The thickness of the final barrier layer is not particularly limited but is preferably 1 nm or more and 40 nm or less.

### <V-Pit Structure>

The “V-pit structure 27” represents a crystal defect caused by threading dislocation and having a shape in which the diameter increases from the inside of the second n-type nitride semiconductor layer 11 to the upper surface (surface located on the p-type nitride semiconductor layer 17 side of the light-emitting layer 15) 15A of the light-emitting layer 15. As described above, the V-pit structure 27 is partially formed in the second n-type nitride semiconductor layer 11, the third n-type nitride semiconductor layer 13, and the light-emitting layer 15.

The sentence “the V-pit structure 27 is partially formed in the second n-type nitride semiconductor layer 11, the third n-type nitride semiconductor layer 13, and the light-emitting layer 15” represents that the V-pit structure 27 having a shape in which the diameter increases from the inside of the second n-type nitride semiconductor layer 11 to the upper surface 15A of the light-emitting layer 15 is scattered in the upper surface 15A of the light-emitting layer 15. The V-pit structure 27 is preferably formed at a surface density of 1×10⁸/cm² or less in the upper surface 15A of the light-emitting layer 15 and more preferably formed at a surface density of 5×10⁷/cm² or less in the upper surface 15A of the light-emitting layer 15. The surface density of the V-pit structure 27 in the upper surface 15A of the light-emitting layer 15 can be determined by, for example, observing the upper surface 15A of the light-emitting layer 15 with an atomic force microscope (AFM).

The average position of the starting point 27C of the V-pit structure 27 is present in the second n-type nitride semiconductor layer 11. The “starting point 27C of the V-pit structure 27” represents an intersection appearing when the side surfaces constituting the V-pit structure 27 are extended to the first n-type nitride semiconductor layer 9 side and, in the V-pit structure 27 shown in FIG. 1, represents a portion located nearest to the first n-type nitride semiconductor layer 9 side. The term “average position of the starting point 27C of the V-pit structure 27” represents a position obtained by averaging the starting point 27C of the V-pit structure 27 in the thickness direction of the nitride semiconductor light-emitting element.

When the average position of the starting point 27C of the V-pit structure 27 is present in the second n-type nitride semiconductor layer 11, the diameter r (hereinafter simply referred to as the “diameter r of the V-pit structure 27”) of the V-pit structure 27 at the lower surface (in the light-emitting layer 15, the surface in contact with the third n-type nitride semiconductor layer 13) 15B of the light-emitting layer 15 can be controlled to be 40 nm or more and 80 nm or less.

When the diameter r of the V-pit structure 27 is 40 nm or more, the size of the V-pit structure 27 can be secured, and thus the electrons or holes can be prevented from being captured by threading dislocation present in the V-pit structure 27, thereby making it possible to prevent the occurrence of nonradiative recombination at threading dislocation. Therefore, the emission efficiency can be enhanced during both the operation at room temperature and the operation at a high temperature, and thus the optical output can be increased. This becomes significant particularly during operation at a high temperature.

In detail, the electron or hole transfer is activated at a higher temperature, thereby increasing the probability that electrons or holes reach threading dislocation. Therefore, the nonradiative dislocation at threading dislocation easily occurs. However, when the diameter r of the V-pit structure 27 is 40 nm or more, the electrons or holes are little captured by threading dislocation present in the V-pit structure 27. Therefore, the occurrence of nonradiative dislocation at threading dislocation can be prevented.

When the diameter r of the V-pit structure 27 is 80 nm or less, the flatness of the upper surface (surface located on the third n-type nitride semiconductor layer 13 side of the second n-type nitride semiconductor layer 11) 11A of the second n-type nitride semiconductor layer 11 can be maintained around the V-pit structure 27, and the flatness of the upper surface (surface located on the light-emitting layer 15 side of the third n-type nitride semiconductor layer 13) 13A of the third n-type nitride semiconductor layer 13 can be maintained around the V-pit structure 27. This can prevent the occurrence of crystal defects in the light-emitting layer 15. Therefore, when the diameter r of the V-pit structure 27 is 80 nm or less, a decrease in emission efficiency due to the formation of the V-pit structure 27 can be prevented. That is, the emission efficiency can be enhanced regardless of the operating temperature of the nitride semiconductor light-emitting element. Therefore, the optical output can be enhanced during both the operation at room temperature and the operation at a high temperature.

Therefore, when the average position of the starting point 27C of the V-pit structure 27 is present in the second n-type nitride semiconductor layer 11, the diameter r of the V-pit structure 27 can be controlled to be 40 nm or more and 80 nm or less, and thus the optical output of the nitride semiconductor light-emitting element can be enhanced both during operation at room temperature and during operation at a high temperature. The diameter r of the V-pit structure 27 is more preferably 45 nm or more and 75 nm or less. The average position of the starting point 27C of the V-pit structure 27 can be confirmed from a TEM (Transmission Electron Microscope) sectional image of the nitride semiconductor light-emitting element, and the diameter r of the V-pit structure 27 can be determined. When two or more V-pit structures 27 are present, the diameter r of the V-pit structures 27 is an average value of the determined diameters.

When the average position of the starting point 27C of the V-pit structure 27 is present in the third n-type nitride semiconductor layer 13, the diameter r of the V-pit structure 27 easily becomes less than 40 nm. When the average position of the starting point 27C of the V-pit structure 27 is present in the first n-type nitride semiconductor layer 11, the diameter r of the V-pit structure 27 easily exceeds 80 nm.

When at least one of the growth conditions for the second n-type nitride semiconductor layer 11 and the growth conditions for the third n-type nitride semiconductor layer 13 is a preferred condition, the average position of the starting point 27C of the V-pit structure 27 is present in the second n-type nitride semiconductor layer 11. Thus, the diameter r of the V-pit structure 27 can be controlled to be 40 nm or more and 80 nm or less.

During growth of the second n-type nitride semiconductor layer 11, a lower temperature of the substrate 1 or a higher growth rate is considered to facilitate the formation of the starting point 27C of the V-pit structure 27, while a higher temperature of the substrate 1 or a lower growth rate is considered to cause difficulty in forming the starting point 27C of the V-pit structure 27. It is considered that the diameter r of the V-pit structure 27 increases with increases in the thickness of the second n-type nitride semiconductor layer 11, and the diameter r of the V-pit structure 27 decreases with decreases in the thickness of the second n-type nitride semiconductor layer 11.

Specifically, the temperature of the substrate 1 during growth of the second n-type nitride semiconductor layer 11 is preferably set to 600° C. or more and 1000° C. or less and more preferably 650° C. or more and 950° C. or less. Also, the growth rate of the second n-type nitride semiconductor layer 11 during growth of the second n-type nitride semiconductor layer 11 is preferably set to 50 nm/h or more and 1000 nm/h or less and more preferably 50 nm/h or more and 500 nm/h or less. In addition, the thickness of the second n-type nitride semiconductor layer 11 is preferably 5 nm or more and 1000 nm or less and more preferably 10 nm or more and 500 nm or less. For example, preferably, the temperature of the substrate 1 is 840° C. or more and 870° C. or less, and the growth rate of the second n-type nitride semiconductor layer 11 is 130 nm/h or more and 200 nm/h or less. Also, preferably, the temperature of the substrate 1 is 800° C. or more and 840° C. or less, and the growth rate of the second n-type nitride semiconductor layer 11 is 50 nm/h or more and 130 nm/h or less. When the second n-type nitride semiconductor layer 11 is grown at a growth rate of 150 nm/h with the substrate 1 set to a temperature of 850° C., the second n-type nitride semiconductor layer 11 is preferably grown until the thickness is 50 nm or more and 300 nm or less.

During growth of the third n-type nitride semiconductor layer 13, a lower temperature of the substrate 1 or a higher growth rate is considered to cause the formation of the V-pit structure 27 to easily proceed, while a higher temperature of the substrate 1 or a lower growth rate is considered to cause the V-pit structure 27 to little proceed. It is considered that the diameter r of the V-pit structure 27 increases with increases in the thickness of the third n-type nitride semiconductor layer 13, and the diameter r of the V-pit structure 27 decreases with decreases in the thickness of the third n-type nitride semiconductor layer 13.

Specifically, the temperature of the substrate during the growth of the third n-type nitride semiconductor layer 13 is preferably set to 600° C. or more and 1000° C. or less and more preferably 650° C. or more and 950° C. or less. Also, the growth rate of the third n-type nitride semiconductor layer 13 during the growth of the third n-type nitride semiconductor layer 13 is preferably set to 50 nm/h or more and 1000 nm/h or less and more preferably 50 nm/h or more and 500 nm/h or less. In addition, the thickness of the third n-type nitride semiconductor layer 13 is preferably 1 nm or more and 50 nm or less and more preferably 1 nm or more and 30 nm or less. For example, preferably, the temperature of the substrate 1 is 840° C. or more and 870° C. or less, and the growth rate of the third n-type nitride semiconductor layer 13 is 130 nm/h or more and 200 nm/h or less. Also, preferably, the temperature of the substrate 1 is 800° C. or more and 840° C. or less, and the growth rate of the third n-type nitride semiconductor layer 13 is 50 nm/h or more and 130 nm/h or less. When the third n-type nitride semiconductor layer 13 is grown at a growth rate of 150 nm/h with the substrate 1 set to a temperature of 850° C., the third n-type nitride semiconductor layer 13 is preferably grown until the thickness is 5 nm or more and 25 nm or less.

The average position of the starting point 27C of the V-pit structure 27 is preferably present 30 nm or more away from the lower surface (in the second n-type nitride semiconductor layer 11, the surface in contact with the first n-type nitride semiconductor layer 9) 11B of the second n-type nitride semiconductor layer 11. In other words, the distance d shown in FIG. 1 is preferably 30 nm or more. Therefore, the diameter r of the V-pit structure 27 can be controlled to be 40 nm or more and 80 nm or less, and thus the optical output of the nitride semiconductor light-emitting element can be easily enhanced during both the operation at room temperature and the operation at a high temperature. The distance d shown in FIG. 1 is more preferably 30 nm or more and 1000 nm or less. The distance d shown in FIG. 1 can be determined from a TEM sectional image of the nitride semiconductor light-emitting element.

When at least one of the growth conditions for the second n-type nitride semiconductor layer 11 is a preferred condition, the distance d shown in FIG. 1 is 30 nm or more. For example, the temperature of the substrate 1 during the growth of the second n-type nitride semiconductor layer 11 is preferably set to 600° C. or more and 1000° C. or less and more preferably 650° C. or more and 950° C. or less. Also, the growth rate of the second n-type nitride semiconductor layer 11 during the growth of the second n-type nitride semiconductor layer 11 is preferably set to 50 nm/h or more and 1000 nm/h or less and more preferably 50 nm/h or more and 500 nm/h or less.

### <P-Type Nitride Semiconductor Layer>

For example, a layer doped with a p-type dopant and composed of a nitride semiconductor material represented by general formula Alₓ₄Gaₓ₄In_{z4}N (0≦x4≦1, 0≦y4≦1, 0≦z4≦1, x4+y4+z4≠0) can be used as the p-type nitride semiconductor layer 17. A layer doped with a p-type dopant and composed of a nitride semiconductor material represented by general formula Alₓ₄Ga₍₁₋ₓ₄₎N (0<x4≦0.4, preferably 0.1≦x4≦0.3) is preferably used as the p-type nitride semiconductor layer 17.

The p-type dopant concentration in the p-type nitride semiconductor layer 17 is preferably 1×10¹⁸/cm³ or more and more preferably 2×10¹⁸/cm³ or more and 2×10²¹/cm³ or less. In addition, magnesium is preferably used as the p-type dopant.

The thickness of the p-type nitride semiconductor layer 17 is not particularly limited but is preferably 50 nm or more and 300 nm or less. When the thickness of the p-type nitride semiconductor layer 17 is 300 nm or less, the heating time during the growth of the p-type nitride semiconductor layer 17 can be shortened. Therefore, diffusion of the p-type dopant from the p-type nitride semiconductor layer 17 to the light-emitting layer 15 can be prevented.

The p-type nitride semiconductor layer 17 may be a single layer or may have a multilayer structure formed by stacking two or more layers different from each other in at least one of the composition and the dopant concentration. When the p-type nitride semiconductor layer 17 has the multilayer structure described above, at least one of the layers constituting the p-type nitride semiconductor layer 17 may be different from other layers in at least one of the composition and the dopant concentration. When the p-type nitride semiconductor layer 17 has the multilayer structure described above, all layers constituting the p-type nitride semiconductor layer 17 may have the same thickness or at least one of the layers constituting the p-type nitride semiconductor layer 17 may have a thickness different from those of other layers.

Also, the light-emitting layer 15 is held between the p-type nitride semiconductor layer 17 and the third n-type nitride semiconductor layer 13, and thus the p-type nitride semiconductor layer 17 also functions as a p-type clad layer.

<N-Side Electrode, p-Side Electrode, Transparent Electrode Layer, and Transparent Insulating Layer>

The transparent electrode layer 19, the p-side electrode 21, and the n-side electrode 23 are electrodes which supply electric power to the nitride semiconductor light-emitting element. Each of the p-side electrode 21 and the n-side electrode 23 may include a pad electrode and may be configured to have a branch electrode connected to a pad electrode for the purpose of diffusing a current.

The transparent electrode layer 19 is preferably composed of, for example, ITO (Indium Tin Oxide), IZO (Indium Zinc Oxide), or the like, and preferably has a thickness of 20 nm or more and 200 nm or less.

Each of the p-side electrode 21 and the n-side electrode 23 is preferably configured by, for example, stacking a nickel layer, an aluminum layer, a titanium layer, and a gold layer in that order. However, the p-side electrode 21 and the n-side electrode 23 may have the same configuration or different configurations. The thickness of each of the p-side electrode 21 and the n-side electrode 23 is not particularly limited but is preferably 1 μm or more assuming that wire bonding is performed on each of the p-side electrode 21 and the n-side electrode 23.

An insulating layer is provided below the p-side electrode 21, preferably below the transparent electrode layer 19, in order to prevent the injection of current directly below the p-side electrode 21. This can decrease the quantity of light shielded by the p-side electrode 21 and thus can enhance the light extraction efficiency.

For example, a SiO₂ film can be used as the transparent insulating layer 25. However, the material of the transparent insulating layer 25 is not limited to SiO₂.

### <Relation Between Carrier Concentration and Dopant Concentration>

The carrier concentration represents the concentration of electrons or holes and is not determined by only the amount of the n-type dopant or p-type dopant. The carrier concentration is calculated based on the results of voltage-to-capacity characteristics of the nitride semiconductor light-emitting element, and indicates the carrier concentration with no current injected, which represents a total of ionized impurities and carriers generated from crystal defects converted to donors and crystal defects converted to acceptors.

The n-type carrier concentration is considered to be substantially the same as the n-type dopant concentration because of the high activation ratio of the n-type dopant (for example, Si). The n-type dopant concentration can be easily determined by measuring a concentration distribution in the depth direction by SIMS (Secondary Ion Mass Spectroscopy). Further, a relative relation (ratio) of the dopant concentration is substantially the same as a relative relation (ratio) of the carrier concentration. Therefore, the present invention uses a dopant concentration which can be actually easily measured.

### [Manufacture of Nitride Semiconductor Light-Emitting Element]

An example of the method for manufacturing the nitride semiconductor light-emitting element according to the embodiment is described below. First, the buffer layer 3 is formed on the upper surface 1A of the substrate 1 by a sputtering method or MOCVD method.

Next, the underlayer 5, the n-type nitride semiconductor layer 7, the light-emitting layer 15, and the p-type nitride semiconductor layer 17 are formed in order on the buffer layer 3 by a MOCVD method, a MBE method, or a VPE method.

The temperature of the substrate 1 during the formation of the underlayer 5 is preferably 800° C. or more and 1250° C. or less. In this case, the underlayer 5 having little crystal defects and excellent crystal quality can be formed. The temperature of the substrate 1 during formation of the underlayer 5 is more preferably 900° C. or more and 1150° C. or less.

When the first n-type nitride semiconductor layer 9 is formed, after a portion of the first n-type nitride semiconductor layer 9 is formed, the substrate 1 on which a portion of the first n-type nitride semiconductor layer 9 has been formed may be taken out from a growth furnace, and then the remaining portion of the first n-type nitride semiconductor layer 9 may be formed in another furnace.

The growth conditions for the second n-type nitride semiconductor layer 11 and the growth conditions for the third n-type nitride semiconductor layer 13 are as described above.

When the underlayer 5, the n-type nitride semiconductor layer 7, the light-emitting layer 15, and the p-type nitride semiconductor layer 17 are formed by a MOCVD method, TMG (trimethylgallium) or TEG (triethylgallium) can be used as a Ga raw material gas. TMA (trimethylaluminum) or TEA (triethylaluminum) can be used as an Al raw material gas. TMI (trimethylindium) or TEI (triethylindium) can be used as an In raw material gas. An organic nitrogen compound such as DMHy (dimethylhydrazine) or the like or NH₃ can be used as an N raw material gas. When Si is used as the n-type dopant, SiH₄, Si₂H₆, or organic Si can be used as an n-type dopant raw material gas. When Mg is used as the p-type dopant, Cp₂Mg can be used as a p-type dopant raw material gas.

Then, the p-type nitride semiconductor layer 17, the light-emitting layer 15, the third n-type nitride semiconductor layer 13, the second n-type nitride semiconductor layer 11, and the first n-type nitride semiconductor layer 9 are partially etched so as to expose a portion of the first n-type nitride semiconductor layer 9. Then, the n-side electrode 23 is formed on the exposed upper surface of the first n-type nitride semiconductor layer 9 exposed by the etching. Also, the transparent electrode layer 19 and the p-side electrode 21 are formed in order on the supper surface of the p-type nitride semiconductor layer 17. Then, the upper surface of the transparent electrode layer 19 and the exposed side surfaces of the layers partially exposed by the etching are covered with the transparent insulating layer 25 so as to expose the upper surfaces of the p-side electrode 21 and the n-side electrode 23. As a result, the nitride semiconductor light-emitting element according to the embodiment is produced.

### Summary of Embodiment

The nitride semiconductor light-emitting element shown in FIG. 1 includes the substrate 1 and the n-type nitride semiconductor layer 7, the light-emitting layer 15 having a single quantum well structure or a multiple quantum well structure, and the p-type nitride semiconductor layer 17 which are provided in order on the substrate 1. The n-type nitride semiconductor layer 7 includes the first n-type nitride semiconductor layer 9, the second n-type nitride semiconductor layer 11, and the third n-type nitride semiconductor layer 13 which are provided in order from the substrate 1 side to the light-emitting layer 15 side. The n-type dopant concentration in the second n-type nitride semiconductor layer 11 is lower than that in the first n-type nitride semiconductor layer 9. The n-type dopant concentration in the third n-type nitride semiconductor layer 13 is higher than that in the second n-type nitride semiconductor layer 11. The V-pit structure 27 is partially formed in the second n-type nitride semiconductor layer 11, the third n-type nitride semiconductor layer 13, and the light-emitting layer 15. The average position of the starting point 27C of the V-pit structure 27 is present in the second n-type nitride semiconductor layer 11. Therefore, the optical output of the nitride semiconductor light-emitting element can be enhanced during both the operation at room temperature and the operation at a high temperature.

The diameter r of the V-pit structure 27 at the lower surface 15B of the light-emitting layer 15 is preferably 40 nm or more and 80 nm or less. Therefore, the optical output of the nitride semiconductor light-emitting element can be easily enhanced during both the operation at room temperature and the operation at a high temperature.

The average position of the starting point 27C of the V-pit structure 27 is preferably present 30 nm or more away from the lower surface 11B of the second n-type nitride semiconductor layer 11. Therefore, the optical output of the nitride semiconductor light-emitting element can be easily enhanced during both the operation at room temperature and the operation at a high temperature.

The third n-type nitride semiconductor layer 13 is preferably composed of GaN or AlGaN. Therefore, even when the light-emitting layer 15 emits light having an emission peak wavelength within a wavelength range of 360 nm or more and 420 nm or less, the light extraction efficiency can be maintained high.

### EXAMPLES

The present invention is described in further detail below by giving examples, but the present invention is not limited to these examples.

### Examples 1 and 2 and Comparative Examples 1 to 5

### Example 1

A sapphire substrate (substrate with a diameter of 100 mm) in which unevenness including recesses and projections was formed in the upper surface thereof was prepared. The projections were provided at positions corresponding to the apexes of a substantially triangle in the upper surface of the sapphire substrate, the distance between the adjacent projections was 2 μm, and the height of the projections was about 0.6 μm. The shape of each of the projections in the upper surface of the sapphire substrate was a substantially circle (diameter of 1.2 μm).

Next, the upper surface of the sapphire substrate was RCA-washed. After RCA washing, the sapphire substrate was placed in a chamber, and then N₂, O₂, and Ar were introduced into the chamber in which the sapphire substrate was then heated to 650° C. Then, a buffer layer (thickness of 35 nm) composed of an AlON crystal was formed on the upper surface of the sapphire substrate by a reactive sputtering method of sputtering an Al target. The AlON crystal was extended in a normal direction to the upper surface of the sapphire substrate and composed of an aggregate of columnar crystals containing uniform crystal grains.

Then, the sapphire substrate on which the buffer layer had been formed was placed in a first MOCVD apparatus. An underlayer (thickness of 3.8 μm) composed of undoped GaN was grown on the upper surface of the buffer layer by the MOCVD method, and then a first n-type nitride semiconductor layer (thickness of 3 μm, n-type dopant concentration of 1×10¹⁹/cm³) composed of Si-doped n-type GaN was grown.

Then, the sapphire substrate was taken out from the first MOCVD apparatus and placed in a second MOCVD apparatus. The temperature of the sapphire substrate was set to 850° C., and an n-type GaN layer (thickness of 74 nm, n-type dopant concentration of 7×10¹⁷/cm³) was grown, and then an undoped GaN layer (thickness of 64 nm) was grown. As a result, a second n-type nitride semiconductor layer (n-type dopant concentration of 5.4×10¹⁷/cm³) including the n-type GaN layer and the undoped GaN layer was formed. The growth rate of each of the n-type GaN layer and the undoped GaN layer was 145 nm/h.

Then, in a state in which the temperature of the sapphire substrate was kept at 850° C., a third n-type nitride semiconductor layer (thickness of 20 nm, n-type dopant concentration of 1.1×10¹⁹/cm³) composed of Si-doped n-type GaN was grown. The growth rate of the third n-type nitride semiconductor layer was 145 nm/h.

Then, the temperature of the sapphire substrate was decreased to 670° C. and a light-emitting layer was grown. Specifically, a barrier layer (thickness of 4 nm) composed of undoped GaN and a quantum well layer (thickness of 3.4 nm) composed of undoped In_{0.2}Ga_{0.8}N were alternately layer-by-layer formed. A first barrier layer (thickness of 4 nm) was formed on the upper surface of the third n-type nitride semiconductor layer. A final barrier layer (thickness of 8 nm) was formed on the uppermost surface of the light-emitting layer.

Then, the temperature of the sapphire substrate was increased to 1200° C. A p-type nitride semiconductor layer including a p-type Al_{0.2}Ga_{0.8}N layer and a p-type GaN layer was grown on the upper surface of the final barrier layer. In order to control the p-type dopant concentration in the p-type nitride semiconductor layer to a final target p-type dopant concentration, the flow rate of a p-type dopant raw material gas was properly changed.

When the nitride semiconductor layers were grown by a MOCVD method, TMG (trimethylgallium) was used as a Ga raw material gas, TMA (trimethylaluminum) was used as an Al raw material gas, TMI (trimethylindium) was used as an In raw material gas, and NH₃ was used as an N raw material gas. Also, SiH₄ was used as an n-type dopant raw material gas, and Cp₂Mg was used as a p-type dopant raw material gas.

Then, the p-type nitride semiconductor layer, the light-emitting layer, the third n-type nitride semiconductor layer, the second n-type nitride semiconductor layer, and the first n-type nitride semiconductor layer were partially etched so as to expose a portion of the first n-type nitride semiconductor layer. Then, an n-side electrode composed of Au was formed on the exposed upper surface of the first n-type nitride semiconductor layer exposed by the etching. Also, a transparent electrode layer composed of ITO and a p-side electrode composed of Au were formed in order on the upper surface of the p-type nitride semiconductor layer. Then, the upper surface of the transparent electrode layer and the exposed side surfaces of the layers partially exposed by the etching were covered with a transparent insulating layer composed of SiO₂ so as to expose the upper surfaces of the p-side electrode and the n-side electrode.

Then, the sapphire substrate was divided to a size of 620×680 μm, and the resultant chip was mounted on a surface-mounted package. The p-side electrode and the n-side electrode were connected to electrodes of the surface-mounted package, and then the chip was sealed with a resin. Consequently, a nitride semiconductor light-emitting element of Example 1 was produced.

The resultant nitride semiconductor light-emitting element was operated at a current of 120 mA, and optical output was measured at room temperature (25° C.) and high temperature (80° C.). The optical output of the nitride semiconductor light-emitting element of this example was 161 mW at 25° C. and 159 mW at 80° C. The emission peak wavelength of the nitride semiconductor light-emitting element of this example was about 450 nm.

In addition, the size and position of the V-pit structure were confirmed without growing the light-emitting layer after the third n-type nitride semiconductor layer was formed according to the method described above. Specifically, the temperature of the sapphire substrate was decreased immediately after the completion of growth of the third n-type nitride semiconductor layer, and the sapphire substrate was taken out from the second MOCVD apparatus. As a result of AFM observation of the upper surface of the third n-type nitride semiconductor layer, it was confirmed that the V-pit structure is formed at a surface density of 4×10⁷/cm² in the upper surface of the third n-type nitride semiconductor layer. It was confirmed by AFM that the diameter r of the V-pit structure is 49 nm. It was confirmed by sectional TEM that the average position of the starting point of the V-pit structure is present in the second n-type nitride semiconductor layer.

### Example 2

In growing a second n-type nitride semiconductor layer and a third n-type nitride semiconductor layer, the temperature of a sapphire substrate was 830° C., and the growth rate was 100 nm/h. Excepting these two points, a nitride semiconductor light-emitting element of Example 2 was produced according to the method described above in Example 1.

The resultant nitride semiconductor light-emitting element was operated at a current of 120 mA, and optical output was measured at room temperature (25° C.) and a high temperature (80° C.). The optical output of the nitride semiconductor light-emitting element of this example was 163 mW at 25° C. and 160 mW at 80° C. The emission peak wavelength of the nitride semiconductor light-emitting element of this example was about 450 nm.

In addition, the size and position of the V-pit structure were confirmed according to the method described above in Example 1. It was confirmed that the V-pit structure is formed at a surface density of 5×10⁷/cm² in the upper surface of the third n-type nitride semiconductor layer. It was also confirmed that the diameter r of the V-pit structure is 74 nm. It was further confirmed that the average position of the starting point of the V-pit structure is present in the second n-type nitride semiconductor layer.

### Comparative Examples 1 to 5

In growing a second n-type nitride semiconductor layer and a third n-type nitride semiconductor layer, the temperature of a sapphire substrate was each of the temperatures shown in Table 1, and the growth rate was each of the rates shown in Table 1. Excepting these two points, a nitride semiconductor light-emitting element of each of Comparative Examples 1 to 5 was produced according to the same method as in Example 1.

According to the method described above in Example 1, the optical output of each of the nitride semiconductor light-emitting elements was measured at 25° C. and 80° C., the surface density of the V-pit structure in the upper surface of the third n-type nitride semiconductor layer was determined, and the diameter r of the V-pit structure was determined. Also, the average position of the starting point of the V-pit structure was confirmed.

### <Results and Consideration>

The results are shown in Table 1 and FIG. 2. In Table 1 and Table 2 described below, “Distance d (nm)*¹¹” represents the distance d shown in FIG. 1, that is, the distance between the average position of the starting point of the V-pit structure and the lower surface of the second n-type nitride semiconductor layer. FIG. 2, Table 1, and Table 2 described below, a diameter r of the V-pit structure of 0 nm represents that the V-pit structure is not formed.

TABLE 1

| | Growth condition for | | Growth condition for | | | | | |
|---|---|---|---|---|---|---|---|---|
| | second n-type nitride | | third n-type nitride | | Diameter | | | |
| | semiconductor layer | | semiconductor layer | | r | | Optical | |
| | Growth | | Growth | | of V-pit | | output | |
| | temperature | Growth rate | temperature | Growth rate | structure | Distanced | (mW) | |
| | (° C.) | (nm/h) | (° C.) | (nm/h) | (nm) | (nm)*¹¹ | 25° C. | 80° C. |
| Example 1 | 850 | 145 | 850 | 145 | 49 | 112 | 161 | 159 |
| Example 2 | 830 | 100 | 830 | 100 | 74 | 88 | 163 | 160 |
| Comparative | 800 | 100 | 800 | 100 | 83 | 80 | 156 | 151 |
| Example 1 | | | | | | | | |
| Comparative | 800 | 145 | 800 | 145 | 91 | 72 | 147 | 142 |
| Example 2 | | | | | | | | |
| Comparative | 830 | 145 | 830 | 145 | 87 | 76 | 151 | 147 |
| Example 3 | | | | | | | | |
| Comparative | 850 | 100 | 850 | 100 | 0 | 0 | 160 | 135 |
| Example 4 | | | | | | | | |
| Comparative | 880 | 145 | 880 | 145 | 0 | 0 | 156 | 135 |
| Example 5 | | | | | | | | |

In Comparative Examples 1 to 3, the diameter r of the V-pit structure is more than 80 nm. Also, both the optical output at 25° C. and the optical output at 80° C. are lower than in Examples 1 and 2.

In Comparative Examples 4 and 5, the diameter r of the V-pit structure is 0 nm, and the V-pit structure is not formed. Also, both the optical output at 25° C. and the optical output at 80° C. are lower than in Examples 1 and 2. In particular, the optical output at 80° C. is significantly decreased as compared with Examples 1 and 2.

On the other hand, in Examples 1 and 2, the diameter r of the V-pit structure is 40 nm or more and 80 nm or less. Also, both the optical output at 25° C. and the optical output at 80° C. are about 160 mW.

The above results show that when the diameter r of the V-pit structure is 40 nm or more and 80 nm or less, both the optical output at 25° C. and the optical output at 80° C. can be enhanced (FIG. 2). Also, when the temperature of the sapphire substrate and the growth rate are optimized in growing the second n-type nitride semiconductor layer and the third n-type nitride semiconductor layer, the average position of the starting point of the V-pit structure is present in the second n-type nitride semiconductor layer, and thus the diameter r of the V-pit structure can be controlled to be 40 nm or more and 80 nm or less.

### Example 3 and Comparative Examples 6 to 10

### Example 3

Layers up to a third n-type nitride semiconductor layer were formed according to the methods described above in Example 1. Then, the temperature of the sapphire substrate was decreased to 710° C., and a light-emitting layer was grown. Specifically, a barrier layer (thickness of 4 nm) composed of undoped Al_{0.05}Ga_{0.95}N and a quantum well layer (thickness of 3.4 nm) composed of undoped In_{0.08}Ga_{0.82}N were alternately layer-by-layer grown. A first barrier layer (thickness of 4 nm) was formed on the upper surface of the third n-type nitride semiconductor layer. A final barrier layer (thickness of 4 nm) was formed on the uppermost surface of the light-emitting layer.

Next, the temperature of the sapphire substrate was increased to 1200° C., and a p-type nitride semiconductor layer was grown according to the method described above in Example 1. Then, the sapphire substrate on which the p-type nitride semiconductor layer had been formed was taken out from the second MOCVD apparatus, and then the sapphire substrate was divided to a size of 440×530 μm according to the method described above in Example 1. The resultant chip was sealed with a resin according to the method described above in Example 1, thereby producing a nitride semiconductor light-emitting element of Example 3.

According to the method described above in Example 1, the optical output of the nitride semiconductor light-emitting element was measured at 25° C. and 80° C. As a result, the optical output was 69 mW at 25° C. and 65 mW at 80° C. The emission peak wavelength of the nitride semiconductor light-emitting element of this example was about 405 nm.

According to the method described above in Example 1, the surface density of the V-pit structure in the upper surface of the third n-type nitride semiconductor layer was determined, the diameter r of the V-pit structure was determined, and the average position of the starting point of the V-pit structure was confirmed. As a result, the same results as in Examples 1 and 2 were obtained.

### Comparative Examples 6 to 10

In growing a second n-type nitride semiconductor layer and a third n-type nitride semiconductor layer, the temperature of a sapphire substrate was each of the temperatures shown in Table 2, and the growth rate was each of the rates shown in Table 2. Excepting these two points, a nitride semiconductor light-emitting element of each of Comparative Examples 6 to 10 was produced according to the same method as in Example 3. The emission peak wavelength of each of the nitride semiconductor light-emitting elements was about 405 nm.

According to the method described above in Example 1, the optical output of each of the nitride semiconductor light-emitting elements was measured at 25° C. and 80° C., the surface density of the V-pit structure in the upper surface of the third n-type nitride semiconductor layer was determined, the diameter r of the V-pit structure was determined, and the average position of the starting point of the V-pit structure was confirmed. As a result, the same results as Comparative Examples 1 to 5 were obtained.

### <Results and Consideration>

The results are shown in Table 2.

TABLE 2

| | Growth condition for | | Growth condition for | | | | | |
|---|---|---|---|---|---|---|---|---|
| | second n-type nitride | | third n-type nitride | | Diameter | | | |
| | semiconductor layer | | semiconductor layer | | r | | Optical | |
| | Growth | | Growth | | of V-pit | | output | |
| | temperature | Growth rate | temperature | Growth rate | structure | Distanced | (mW) | |
| | (° C.) | (nm/h) | (° C.) | (nm/h) | (nm) | (nm)*¹¹ | 25° C. | 80° C. |
| Example 3 | 850 | 145 | 850 | 145 | 49 | 112 | 69 | 65 |
| Comparative | 800 | 100 | 800 | 100 | 83 | 80 | 66 | 63 |
| Example 6 | | | | | | | | |
| Comparative | 800 | 145 | 800 | 145 | 91 | 72 | 65 | 62 |
| Example 7 | | | | | | | | |
| Comparative | 830 | 145 | 830 | 145 | 87 | 76 | 67 | 64 |
| Example 8 | | | | | | | | |
| Comparative | 850 | 100 | 850 | 100 | 0 | 0 | 67 | 60 |
| Example 9 | | | | | | | | |
| Comparative | 880 | 145 | 880 | 145 | 0 | 0 | 66 | 57 |
| Example 10 | | | | | | | | |

Table 2 indicates that even in the case of the nitride semiconductor light-emitting element having an emission peak wavelength of about 405 nm, when the diameter r of the V-pit structure is 40 nm or more and 80 nm or less, both the optical output at 25° C. and the optical output at 80° C. can be enhanced. Thus, it was found that when the diameter r of the V-pit structure is 40 nm or more and 80 nm or less, both the optical output at 25° C. and the optical output at 80° C. can be enhanced regardless of the emission peak wavelength of the nitride semiconductor light-emitting element.

The embodiments and examples disclosed herein should be considered to be in every respect exemplary, but not restrictive. The scope of the present invention is shown by the claims, not the description above, and is intended to include meanings equivalent to the claims and all changes within the scope.

### REFERENCE SIGNS LIST

1 substrate, 1A, 11A, 13A, 15A upper surface, 3 buffer layer, 5 underlayer, 7 n-type nitride semiconductor layer, 9 first n-type nitride semiconductor layer, 11 second n-type nitride semiconductor layer, 11B, 15B lower surface, 13 third n-type nitride semiconductor layer, 15 light-emitting layer, 17 p-type nitride semiconductor layer, 19 transparent electrode layer, 21 p-side electrode, 23 n-side electrode, 25 transparent insulating layer, 27 V-pit structure, 27C starting point.

1: A nitride semiconductor light-emitting element comprising:
a substrate; and
an n-type nitride semiconductor layer, a light-emitting layer having a single quantum well structure or a multiple quantum well structure, and a p-type nitride semiconductor layer which are provided in order on the substrate,
wherein the n-type nitride semiconductor layer includes a first n-type nitride semiconductor layer, a second n-type nitride semiconductor layer, and a third n-type nitride semiconductor layer which are provided in order from the substrate side to the light-emitting layer side;
the n-type dopant concentration in the second n-type nitride semiconductor layer is lower than that in the first n-type nitride semiconductor layer;
the n-type dopant concentration in the third n-type nitride semiconductor layer is higher than that in the second n-type nitride semiconductor layer;
a V-pit structure is partially formed in the second n-type nitride semiconductor layer, the third n-type nitride semiconductor layer, and the light-emitting layer; and
the average position of the starting point of the V-pit structure is present in the second n-type nitride semiconductor layer.

2: The nitride semiconductor light-emitting element according to claim 1, wherein the diameter of the V-pit structure at the lower surface of the light-emitting layer is 40 nm or more and 80 nm or less.

3: The nitride semiconductor light-emitting element according to claim 1, wherein the average position of the starting point of the V-pit structure is present 30 nm or more away from the lower surface of the second n-type nitride semiconductor layer.

4: The nitride semiconductor light-emitting element according to claim 1, wherein the third n-type nitride semiconductor layer is composed of GaN or AlGaN.
